(19) United States
(12) Patent Application Publication
(10) Pub. No.: US 2007/0024367 A1
(43) Pub. Date: Feb. 1, 2007

(54) Operational amplifier and constant-current generation circuit using the same

(75) Inventor: Kazuhiko Oyama, Miyazaki (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/406,328

(22) Filed: Apr. 19, 2006

(30) Foreign Application Priority Data
Jul. 27, 2005 (JP) 2005-216828

(51) Int. Cl. H03F 3/45

(52) U.S. Cl. 330/255

(57) ABSTRACT

Provided in a constant-current generation circuit is an OP AMP which includes a bias circuit, differential stage and amplification stage. In the OP AMP, a capacitance is provided between a control terminal which receives a start-up signal EN and a node NGATE. In a start-up operation of the circuit, the node NGATE can more rapidly rise from a VSS to a predetermined voltage by rising a specific voltage in synchronously with a switching timing of the start-up signal EN by virtue of a coupling effect.

### BACKGROUND OF THE INVENTION

1. Field of the Invention

The present invention relates to an operational amplifier (referred to hereinafter as an “OP AMP”) which needs to be started up at high speed and a constant-current generation circuit using the same, in a semiconductor device or the like.

2. Description of the Related Art

One example of conventional constant-current generation circuits using OP AMPs is disclosed in Patent Reference 1, Japanese Patent Laid-open Publication Kokai No. H05-313765.

A constant-current generation circuit shown in FIG. 3 of the Patent Reference 1 comprises an OP AMP constituting a negative feedback bias circuit, a P-channel MOS transistor (referred to hereinafter as a “PMOS”) having a gate connected to an output terminal of the OP AMP and functioning as a current source, a reference resistor connected between the source of the PMOS and a supply voltage (referred to hereinafter as a “VDD”) node, and a load resistor connected between the drain of the PMOS and a ground voltage (referred to hereinafter as a “VSS”) node. The source of the PMOS is feedback-connected to an inverting input terminal of the OP AMP and a reference voltage is input to a non-inverting input terminal of the OP AMP.

In the constant-current generation circuit, the reference voltage is applied to the non-inverting input terminal of the OP AMP and a bias voltage output from the output terminal of the OP AMP is supplied to the gate of the PMOS, thereby allowing output current of the PMOS to flow to the load resistor. The value of the output current is detected by a voltage drop across the reference resistor and then negative feedback-input to the inverting input terminal of the OP AMP. For this reason, the OP AMP generates the bias voltage to the PMOS to make the reference voltage and the voltage drop across the reference resistor equal, so as to make the output current constant irrespective of the resistance of the load resistor.

In order to turn off the output current of the PMOS, it is necessary to vary the reference voltage to the non-inverting input terminal of the OP AMP to make it equal to a VDD, resulting in a large amount of time being required in turning on/off the output current. To solve the problem, in FIG. 1 of the Patent Reference 1, a first switch is provided between the output terminal of the OP AMP and the gate of the PMOS to turn on/off the supply of the bias voltage from the output terminal of the OP AMP to the gate of the PMOS, and a second switch is provided to, when the first switch is turned off, supply a voltage to the gate of the PMOS to turn off the PMOS. As a result, the PMOS can be turned on/off at high speed.

The OP AMP used in the conventional constant-current generation circuit generally has a differential stage for amplifying the difference between two inputs, and an amplification stage for amplifying the output of the differential stage to output the bias voltage. A phase compensation margin is secured by setting the gain (=output voltage/input voltage) of the differential stage to a small value and the gain of the amplification stage to a large value, respectively.

The output voltage of the differential stage of the OP AMP changes to a predetermined or certain voltage level based on the voltage level difference between the two inputs in a start-up operation of the constant-current generation circuit. However, because the gain of the differential stage is set to the small value, a long time is taken until the output voltage reaches the predetermined voltage level. As a result, a lengthy period of time is required until constant current is obtained at the output terminal of the constant-current generation circuit after the circuit is started up.

### SUMMARY OF THE INVENTION

The present invention has been made in view of the above problems, and it is an object of the present invention to provide an OP AMP which can be started up at high speed and a constant-current generation circuit using the same.

In accordance with an aspect of the present invention, the above and other objects can be accomplished by the provision of an operational amplifier (OP AMP) including a first input terminal for receiving a first input signal, a second input terminal for receiving a second input signal, a control terminal for receiving a start-up signal which makes transitions to a first logic level and a second logic level, an output terminal, reset means, a differential stage, an amplification stage, and a capacitance.

The reset means resets a first node to a second voltage, a second node to a first voltage which is different from the second voltage and the output terminal to the second voltage, respectively, when the start-up signal input to the control terminal indicates the first logic level. The reset means may also disconnect the first node from the second voltage, the second node from the first voltage and the output terminal from the second voltage, respectively, when the start-up signal is changed from the first logic level to the second logic level.

The differential stage is made active when the start-up signal is changed to the second logic level and a voltage of the first node makes a transition to a predetermined or certain level. As the differential stage is made active, it may amplify a difference between the first input signal input to the first input terminal and the second input signal input to the second input terminal and output the amplified difference to the second node. The amplification stage may be made active when the voltage of the first node makes the transition to the certain level. As the amplification stage is made active, it may amplify a voltage of the second node and output the amplified voltage to the output terminal. The capacitance may be connected between the control terminal and the second node.

In accordance with another aspect of the present invention, there is provided an OP AMP including a first input terminal for receiving a first input signal, a second input terminal for receiving a second input signal, a control terminal for receiving a start-up signal which makes transitions to a first logic level and a second logic level, an output terminal, reset means, a differential stage, an amplification stage, and first and second switching means.

The reset means resets a first node to a second voltage, a second node to a first voltage which is different from the second voltage and the output terminal to the second voltage, respectively, when the start-up signal input to the control terminal indicates the first logic level. The reset means may also disconnect the first node from the second voltage, the second node from the first voltage and the output terminal from the second voltage, respectively, when the start-up signal is changed from the first logic level to the second logic level.

The differential stage is made active when the start-up signal is changed to the second logic level and a voltage of the first node makes a transition to a predetermined or certain level. As the differential stage is made active, it may amplify a difference between the first input signal input to the first input terminal and the second input signal input to the second input terminal and output the amplified difference from an output node thereof to the second node. The amplification stage may be made active when the voltage of the first node makes the transition to the certain level. As the amplification stage is made active, it may amplify a voltage of the second node and output the amplified voltage to the output terminal.

The first switching means fixes the output node at the second voltage when the start-up signal indicates the first logic level. The first switching means may also disconnect the output node from the second voltage to make the differential stage active, when the start-up signal is changed from the first logic level to the second logic level. The second switching means may isolate the output node and the second node from each other when the start-up signal indicates the first logic level and connect the output node and the second node with each other when the start-up signal is changed from the first logic level to the second logic level.

In accordance with yet another aspect of the present invention, there is provided a constant-current generation circuit including the OP AMP according to the first or second aspect of the present invention, and a transistor for outputting constant current in response to an output signal from the output terminal of the OP AMP, wherein a reference voltage is input to the first input terminal of the OP AMP and a voltage based on the output current from the transistor is feedback-input to the second input terminal of the OP AMP.

In the OP AMP according to the first aspect of the present invention and the constant-current generation circuit using the same, the capacitance is provided between the control terminal that receives the start-up signal and the second node. Thus, in a start-up operation of the constant-current generation circuit, the second node, which is at the output side of the differential stage, can more rapidly rise to a predetermined or certain voltage level by rising to a specific voltage level in advance synchronously with a switching timing of the start-up signal by virtue of a coupling effect. Therefore, in the constant-current generation circuit, it is possible to reduce a time required until constant current is obtained after start-up under the condition of setting the gain of the differential stage of the OP AMP to a small value.

In the OP AMP according to the second aspect of the present invention and the constant-current generation circuit using the same, the first and second switching means are provided in the OP AMP. Thus, in a start-up operation of the constant-current generation circuit, a short circuit is formed between the output node of the differential stage, fixed at a predetermined or certain voltage in a reset period, and the second node at the output side of the differential stage, fixed at a predetermined or certain voltage in the reset period. As a result, the voltage of the second node can more rapidly rise to a predetermined or certain voltage level by rising to a specific voltage level in advance synchronously with a switching timing of the start-up signal. Therefore, in the constant-current generation circuit, it is possible to reduce a time required until constant current is obtained after start-up under the condition of setting the gain of the differential stage of the OP AMP to a small value. This can be adequately attained by the addition of only the first and second switching means, so that the circuit can be implemented in a smaller layout space.

According to another aspect of the present invention there is provided an operational amplifier which includes a first input terminal for receiving a first input signal; a second input terminal for receiving a second input signal; a control terminal for receiving a start-up signal which makes transitions to a first logic level and a second logic level; an output terminal; reset means for resetting a first node to a second voltage, a second node to a first voltage which is different from the second voltage and the output terminal to the second voltage, respectively, when the start-up signal input to the control terminal indicates the first logic level, and disconnecting the first node from the second voltage, the second node from the first voltage and the output terminal from the second voltage, respectively, when the start-up signal is changed from the first logic level to the second logic level; a differential stage made active when the start-up signal is changed to the second logic level and a voltage of the first node makes a transition to a predetermined level, for amplifying a difference between the first input signal input to the first input terminal and the second input signal input to the second input terminal and outputting the amplified difference to the second node; an amplification stage made active when the voltage of the first node makes the transition to the predetermined level, for amplifying a voltage of the second node and outputting the amplified voltage to the output terminal; and a voltage increasing circuit which increases the voltage of the second node to a specific voltage level in response to a switching of the start-up signal from the first logic level to the second logic level.

According to further another aspect of the present invention there is provided a constant-current generation circuit which includes the operational amplifier, and a transistor for outputting constant current in response to an output signal from the output terminal of the operational amplifier, wherein a reference voltage is input to the first input terminal of the operational amplifier and a voltage based on the output current from the transistor is feedback-input to the second input terminal of the operational amplifier.

According to still another aspect of the present invention the constant-current generation circuit further includes third switching means for fixing the second input terminal of the operational amplifier at the first voltage when the start-up signal indicates the first logic level and disconnecting the second input terminal from the first voltage when the start-up signal is changed from the first logic level to the second logic level.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram showing the configuration of an OP AMP 3 according to a first embodiment of the present invention;

FIG. 2 is a circuit diagram showing the configuration of a constant-current generation circuit according to the first embodiment of the present invention;

FIG. 3 is a waveform diagram of respective signals in an OP AMP 3A when the OP AMP 3A is started up;

FIG. 4 illustrates a waveform diagram in which the waveforms of the respective signals of FIG. 3 are arranged;

FIG. 5 is a waveform diagram of respective signals in the OP AMP 3 of FIG. 1 when the OP AMP 3 is started up;

FIG. 6 illustrates a waveform diagram in which the waveforms of the respective signals of FIG. 5 are arranged;

FIG. 7 is a circuit diagram showing the configuration of an OP AMP 3B according to a second embodiment of the present invention;

FIG. 8 is a waveform diagram of respective signals in the OP AMP 3B of FIG. 7 when the OP AMP 3B is started up; and

FIG. 9 illustrates a waveform diagram in which the waveforms of the respective signals of FIG. 8 are arranged.

### DETAILED DESCRIPTION OF THE INVENTION

According to the present invention, an OP AMP comprises a first input terminal for receiving a first input signal, a second input terminal for receiving a second input signal, a control terminal for receiving a start-up signal which makes transitions to a first logic level (for example, an “L” level) and a second logic level (for example, an “H” level), an output terminal, reset means, a differential stage, an amplification stage, and a capacitance.

The reset means operates to reset a first node to a second voltage (for example, an “H”), a second node to a first voltage (for example, an “L”) and the output terminal to the second voltage, respectively, when the start-up signal input to the control terminal indicates the first logic level. The reset means also operates to disconnect the first node from the second voltage, the second node from the first voltage and the output terminal from the second voltage, respectively, when the start-up signal is changed from the first logic level to the second logic level.

The differential stage is made active at the time when the start-up signal is changed to the second logic level and a voltage of the first node makes a transition to a predetermined or certain level. As the differential stage is made active, it amplifies the difference between the first input signal input to the first input terminal and the second input signal input to the second input terminal and outputs the amplified difference to the second node. The amplification stage is made active at the time when the voltage of the first node makes the transition to the predetermined level. As the amplification stage is made active, it amplifies the voltage of the second node and outputs the amplified voltage to the output terminal.

The capacitance is connected between the control terminal and the second node. In a start-up operation, the second node, which is at the output side of the differential stage, can more rapidly rise from the first voltage “L” to a predetermined or certain voltage level by rising to a specific voltage level in advance synchronously with a switching timing of the start-up signal by virtue of a coupling effect by the capacitance.

### FIRST EMBODIMENT

(Configuration of the First Embodiment)

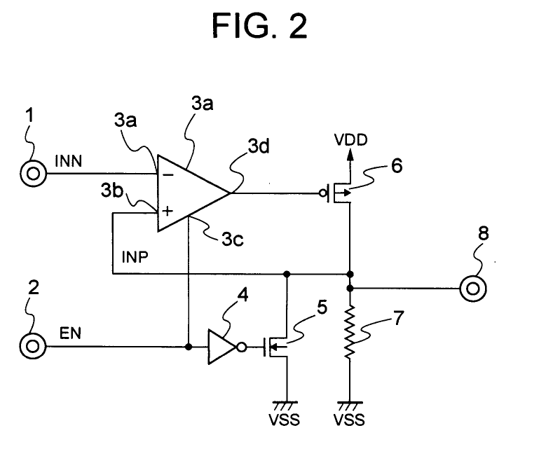

FIG. 2 is a circuit diagram of a constant-current generation circuit according to a first embodiment of the present invention.

The constant-current generation circuit comprises an input terminal 1 for receiving a first input signal (for example, an input voltage which is a reference voltage) INN, an input terminal 2 for receiving a start-up signal EN, and an OP AMP 3 constituting a negative feedback bias circuit and having a first input terminal (for example, an inverting input terminal) 3a, a second input terminal (for example, a non-inverting input terminal) 3b, a control terminal 3c and an output terminal 3d. The input terminal 1 is connected to the inverting input terminal 3a of the OP AMP 3. The input terminal 2 is connected directly to the control terminal 3c of the OP AMP 3 and through an inverter 4 for signal inversion to the gate of a third switching means, for example, an N-channel MOS transistor (referred to hereinafter as an “NMOS”) 5.

The source of the NMOS 5 is connected to a VSS node and the drain thereof is connected in common to the non-inverting input terminal 3b of the OP AMP 3, which receives a second input signal (for example, a feedback voltage) INP, and the drain of a transistor (for example, a PMOS) 6 functioning as a current source. The output terminal 3d of the OP AMP 3, which outputs an output voltage OUT, is connected to the gate of the PMOS 6, the source of which is connected to a VDD node. The drain of the PMOS 6 is connected through a load resistor 7 to the VSS node and directly to an output terminal 8 that outputs constant current corresponding to the input voltage INN.

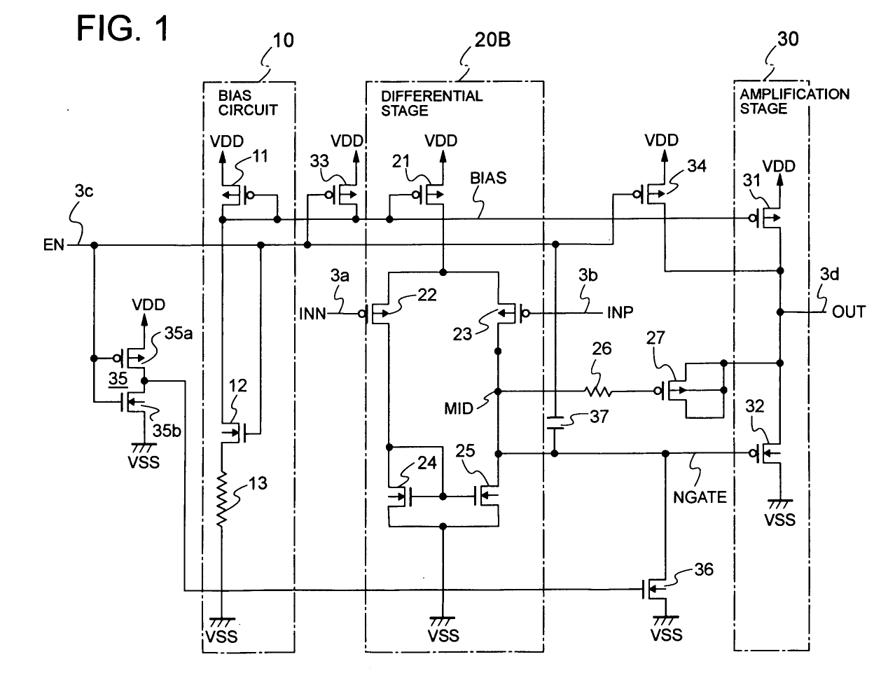

FIG. 1 is a circuit diagram of the OP AMP 3 in FIG. 2 in the first embodiment of the present invention. The OP AMP 3 includes a bias circuit 10 functioning as a current source and made active in response to a second logic level (for example, an “H” level) of the start-up signal EN for supplying constant current, a differential stage 20 for amplifying the difference between the input voltage INN input to the inverting input terminal 3a and the feedback voltage INP input to the non-inverting input terminal 3b and outputting the amplified difference from an output node MID thereof to a second node NGATE, an amplification stage 30 for amplifying the voltage of the second node NGATE and outputting the amplified voltage as the output voltage OUT from the output terminal 3d, and a resistor 26 and MOS capacitance 27 for phase compensation. The MOS capacitance 27 is composed of a PMOS.

The bias circuit 10 includes a PMOS 11, an NMOS 12 and a resistor 13, which are connected in series between the VDD node and the VSS node. The PMOS 11 has a drain and gate connected in common to a first node BIAS. The NMOS 12 has a gate connected to the control terminal 3c, which receives the start-up signal EN.

The differential stage 20 is made up of PMOSs 21, 22 and 23, and NMOSs 24 and 25. The PMOS 21 has a gate connected to the node BIAS and a source connected to the VDD node. The drain of the PMOS 21 is connected in common to the sources of the PMOSs 22 and 23, the gate of the PMOS 22 is connected to the inverting input terminal 3a which receives the voltage INN, and the gate of the PMOS 23 is connected to the non-inverting input terminal 3b which receives the voltage INP. The drain of the PMOS 22 is connected in common to the drain and gate of the NMOS 24, the source of which is connected to the VSS node. The drain of the PMOS 23 is connected through the output node MID to the drain of the NMOS 25, the source of which is connected to the VSS node. The amplification stage 30 is connected to the output node MID through the resistor 26 and MOS capacitance 27. It is also connected to the output node MID through the second node NGATE.

The amplification stage 30 includes a PMOS 31, the output terminal 3d and an NMOS 32, which are connected in series between the VDD node and the VSS node. The PMOS 31 has a source connected to the VDD node, a gate connected to the node BIAS and a drain connected in common to the MOS capacitance 27 and the drain of the NMOS 32 through the output terminal 3d. The NMOS 32 has a gate connected to the node NGATE and a source connected to the VSS node.

Further provided in the OP AMP 3 is reset means which resets the OP AMP 3 when the start-up signal EN input to the control terminal 3c indicates a first logic level (for example, an “L” level). The reset means is made up of PMOSs 33 and 34, an inverter 35, and an NMOS 36. The PMOS 33 operates to fix the node BIAS at a second voltage (for example, a VDD, “H”) in a resetting operation. To this end, the PMOS 33 has a source connected to the VDD node, a gate connected to the control terminal 3c and a drain connected to the node BIAS. The PMOS 34 operates to fix the output terminal 3d at the second voltage (for example, the VDD, “H”) in the resetting operation. To this end, the PMOS 34 has a source connected to the VDD node, a gate connected to the control terminal 3c and a drain connected to the output terminal 3d. The inverter 35 operates to invert the start-up signal EN. To this end, the inverter 35 includes a PMOS 35a and NMOS 35b connected in series between the VDD node and the VSS node. The NMOS 36 operates to fix the node NGATE at a first voltage (for example, a VSS, “L”) in the resetting operation. To this end, the NMOS 36 has a drain connected to the node NGATE, a gate connected to an output terminal of the inverter 35 and a source connected to the VSS node.

Further, a capacitance 37, which is a feature of the present first embodiment, is connected between the control terminal 3c and the node NGATE in the OP AMP 3.

The feature of the present first embodiment is that the capacitance 37 is provided in the OP AMP 3. First, a description will be given of a start-up operation of a constant-current generation circuit which includes an OP AMP (hereinafter denoted by reference numeral “3A”) when the capacitance 37 is not provided.

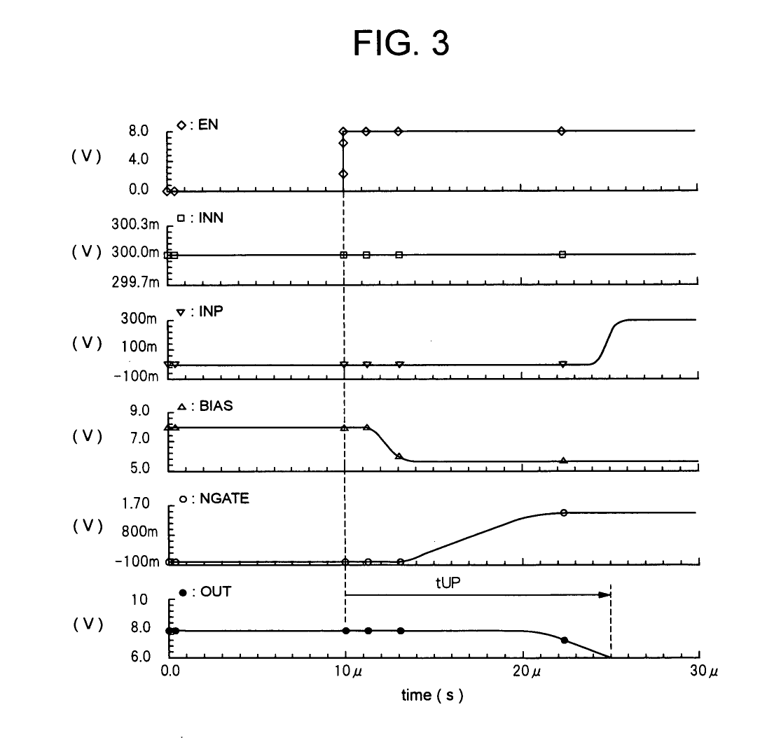

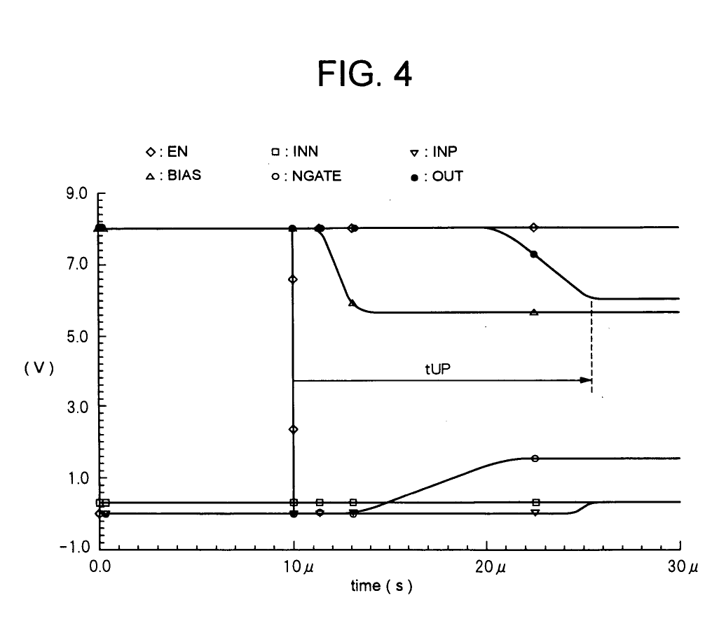

FIG. 3 is a waveform diagram of respective signals in the OP AMP 3A when the OP AMP 3A is started up, wherein each axis of abscissa represents time (time) and each axis of ordinate represents voltage (V). FIG. 4 illustrates a waveform diagram in which the waveforms of the respective signals of FIG. 3 are arranged, wherein the axis of abscissa represents time (time) and the axis of ordinate represents voltage (V).

First, in a reset period (a time from 0 to 10 μs in FIG. 3 and FIG. 4), the start-up signal EN input to the input terminal 2 of the constant-current generation circuit indicates the “L” level (=VSS), thereby causing the PMOSs 33 and 34 in the OP AMP 3A to be turned on and the NMOS 12 therein to be turned off. Also, the start-up signal EN is inverted from the “L” level to the “H” level (=VDD) by the inverter 35, thereby causing the NMOS 36 to be turned on. As a result, the node BIAS is fixed at the VDD, the node NGATE is fixed at the VSS, the output voltage OUT is fixed at the VDD, and a current path from the VDD node to the VSS node is thus cutoff. Also, since the output voltage OUT of the OP AMP 3A is fixed at the VDD, the PMOS 6 in the constant-current generation circuit is turned off and all current paths therein are thus cut. At the same time, the start-up signal EN is inverted from the “L” level to the “H” level by the inverter 4, thereby causing the NMOS 5 to be turned on. As a result, the output terminal 8 is fixed at the VSS.

Thereafter, at the time when the start-up signal EN becomes the “H” level (=VDD) (a time 10 μs), in the OP AMP 3A, the PMOS 33 is turned off, the NMOS 12 is turned on, and the voltage of the node BIAS thus falls from the VDD to the vicinity of a voltage level VDD-Vtp (where Vtp is a threshold value of the PMOS 11). When the voltage of the node BIAS falls to the voltage level VDD-Vtp, the PMOS 21 in the differential stage 20 is turned on, so that the differential stage 20 is made active. Also, the PMOS 31 in the amplification stage 30 is turned on, so that the amplification stage 30 is made active. Thus, the voltage of the node NGATE rises from the VSS to a predetermined or certain voltage level and the output voltage OUT falls from the VDD to the predetermined voltage level by the NMOS 32, thereby making the feedback voltage INP of the OP AMP 3A equal to the input voltage INN thereof.

As the feedback voltage INP becomes equal to the input voltage INN in this manner, at the output terminal 8 of the constant-current generation circuit can be obtained constant current that is determined depending on only the level of the input voltage INN and the resistance of the resistor 7 irrespective of the VDD level. However, a problem occurs as follows.

In the OP AMP 3A, a phase compensation margin is generally secured by setting the gain (=output voltage/input voltage) of the differential stage 20 to a small value and the gain of the amplification stage to a large value, respectively.

In the start-up operation of the constant-current generation circuit, the voltage of the node NGATE, which is at the output side of the differential stage 20, is changed to the predetermined voltage level based on the level difference between the input voltage INN and feedback voltage INP of the differential stage 20 as stated above. However, because the gain of the differential stage 20 is set to the small value, a long time is taken until the voltage of the node NGATE reaches the predetermined voltage level. As a result, a long time (a time tUP in FIG. 3 and FIG. 4) is also taken until the output voltage OUT of the OP AMP 3A reaches the predetermined voltage level, resulting in a lengthy period of time being required until constant current is obtained at the output terminal 8 of the constant-current generation circuit after the circuit is started up.

In order to solve the problem, in the present first embodiment, the capacitance 37 is provided between the control terminal 3c and the node NGATE in the OP AMP 3. The operation of the first embodiment will hereinafter be described.

(Operation of First Embodiment With Capacitance 37)

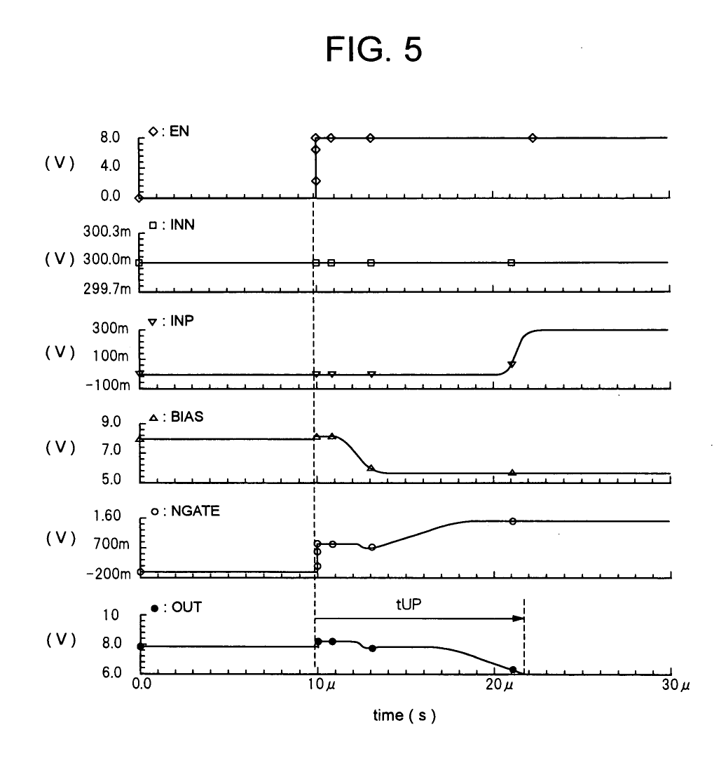

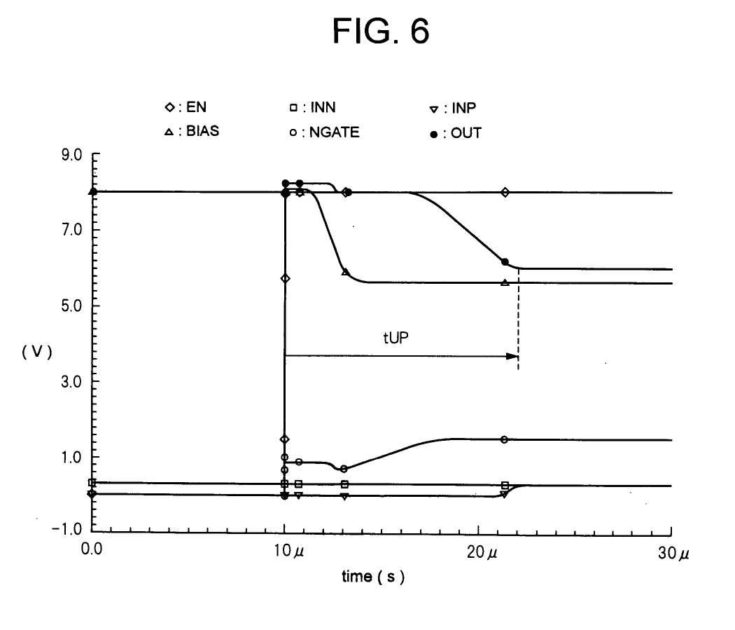

FIG. 5 is a waveform diagram of respective signals in the OP AMP 3 of FIG. 1 when the OP AMP 3 is started up, wherein each axis of abscissa represents time (time) and each axis of ordinate represents voltage (V). FIG. 6 illustrates a waveform diagram in which the waveforms of the respective signals of FIG. 5 are arranged, wherein the axis of abscissa represents time (time) and the axis of ordinate represents voltage (V).

First, the operation in the reset period is performed in the same manner as that described above.

Thereafter, at the time when the start-up signal EN is changed from the “L” level (=VSS) to the “H” level (=VDD), the PMOSs 33 and 34 are turned off, the NMOS 12 is turned on, the NMOS 36 is turned off, and the voltage of the node BIAS thus falls from the VDD to the vicinity of the voltage level VDD−Vtp, in the OP AMP 3, similarly to those in the above-stated operation. As a result, the PMOSs 21 and 31 are turned on, so that the differential stage 20 and the amplification stage 30 are made active. Then, in order to make the feedback voltage INP equal to the input voltage INN, the voltage of the node NGATE rises from the VSS to the predetermined voltage level. At this time, in the present first embodiment, because the capacitance 37 is provided between the control terminal 3c that receives the start-up signal EN and the node NGATE, the voltage of the node NGATE rises from the VSS to a specific voltage level in response to a switching (“L” level→“H” level) timing of the start-up signal EN by virtue of a coupling effect between the control terminal 3c and the node NGATE.

The specific voltage level to which the voltage of the node NGATE rises is determined by the value of the VDD, the value of the capacitance 37 and the value of a parasitic capacitance of the node NGATE. Assuming that the value of the capacitance 37 is C1 and the value of the parasitic capacitance of the node NGATE is C2, the logical value of the specific voltage level can be expressed as in the following equation 1.
{C1/(C1+C2)}·VDD (1)

Thereafter, the voltage of the node NGATE rises to the predetermined voltage level and the output voltage OUT falls from the VDD to the predetermined voltage level, thereby making the feedback voltage INP equal to the input voltage INN. Hence, constant current can be obtained at the output terminal 8 similarly to the above.

(Effect of First Embodiment)

According to the present first embodiment, the capacitance 37 is provided between the control terminal 3c that receives the start-up signal EN and the node NGATE. Thus, in the start-up operation of the constant-current generation circuit, the node NGATE at the output side of the differential stage 20 can more rapidly rise from the VSS to the predetermined voltage level by rising to the specific voltage level in advance synchronously with the switching timing of the start-up signal EN by virtue of the coupling effect. Therefore, in the constant-current generation circuit, it is possible to reduce a time required until constant current is obtained at the output terminal 8 after start-up under the condition of setting the gain of the differential stage 20 of the OP AMP 3 to the small value.

### SECOND EMBODIMENT

(Configuration of Second Embodiment)

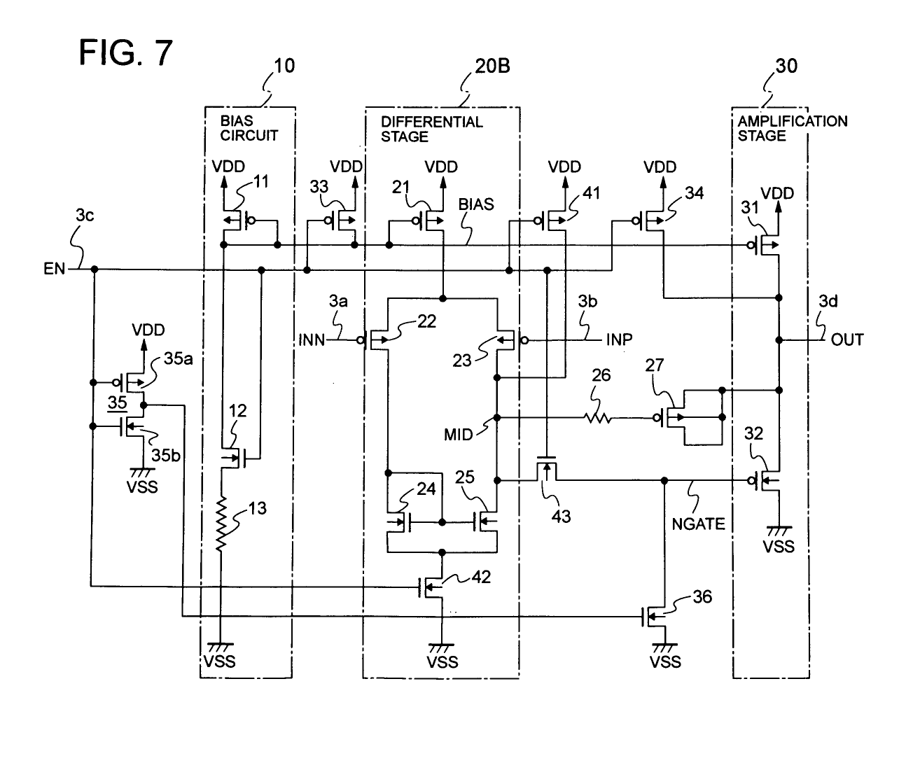

FIG. 7 is a circuit diagram showing the configuration of an OP AMP 3B according to a second embodiment of the present invention. Some parts in the OP AMP 3B of the second embodiment are substantially the same as those in the OP AMP 3 of the first embodiment shown in FIG. 1 and thus denoted by the same reference numerals.

The OP AMP 3B of the present second embodiment is provided instead of the OP AMP 3 in the constant-current generation circuit of FIG. 2. In detail, in the OP AMP 3B of the second embodiment, first switching means (for example, a PMOS 41 and NMOS 42) and second switching means (for example, an NMOS 43) are provided instead of the capacitance 37 in the OP AMP 3 of FIG. 1.

That is, in contrast with the circuit configuration of FIG. 1, the output node MID of the differential stage 20B and the node NGATE connected to the amplification stage 30 are isolated from each other by the NMOS 43, which receives the start-up signal EN at its gate. The sources of the NMOS 24 and NMOS 25 of the differential stage 20B are connected in common to the drain of the newly added NMOS 42, the gate of which is connected to the control terminal 3c and the source of which is connected to the VSS node. The PMOS 41 is further provided to fix the voltage of the output node MID in the resetting operation. The other parts are the same in configuration as those in the OP AMP 3 of FIG. 1.

(Operation of Second Embodiment)

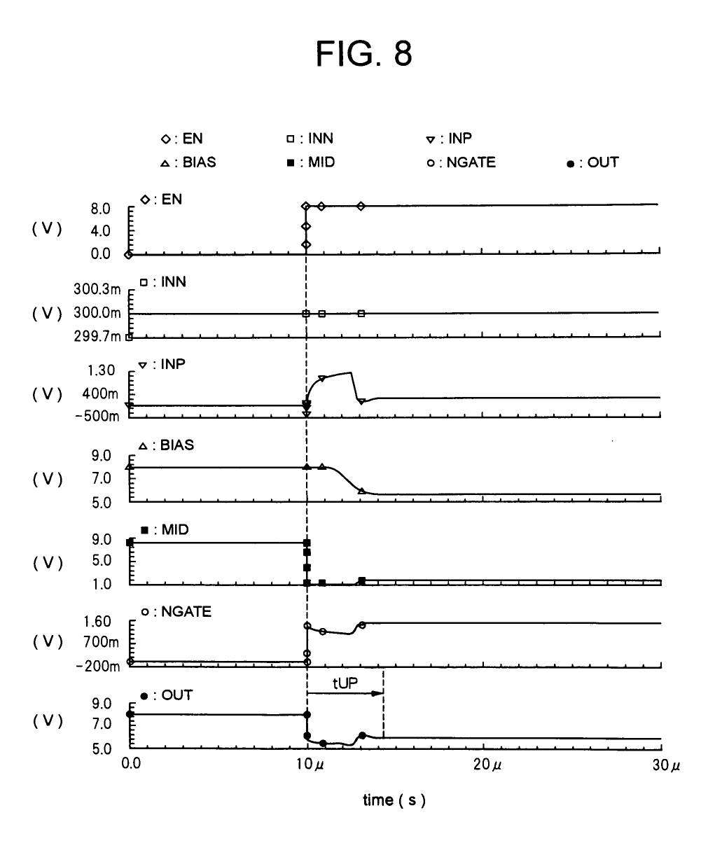

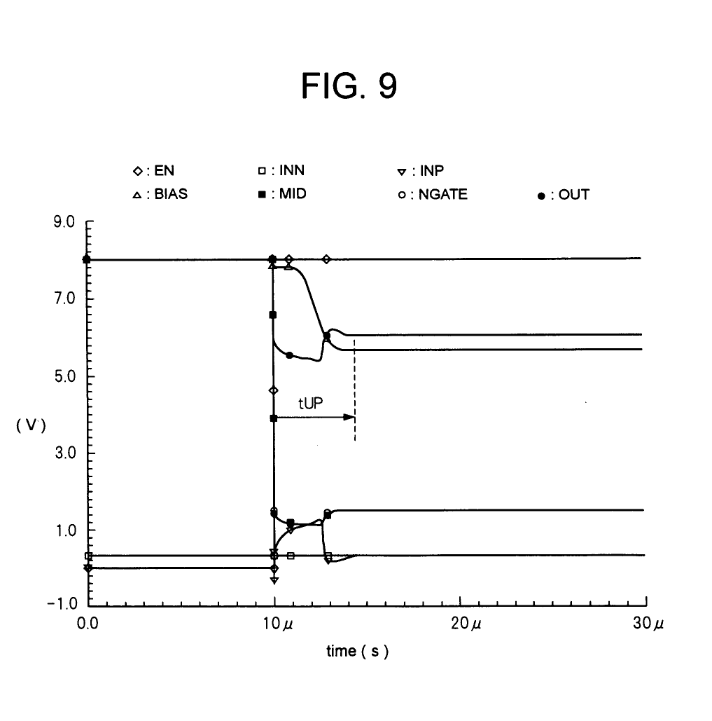

FIG. 8 is a waveform diagram of respective signals in the OP AMP 3B of FIG. 7 when the OP AMP 3B is started up, wherein each axis of abscissa represents time (time) and each axis of ordinate represents voltage (V). FIG. 9 illustrates a waveform diagram in which the waveforms of the respective signals of FIG. 8 are arranged, wherein the axis of abscissa represents time (time) and the axis of ordinate represents voltage (V).

First, in the reset period (a time from 0 to 10 μs in FIG. 8 and FIG. 9), the start-up signal EN input to the control terminal 3c indicates the “L” level (=VSS), thereby causing the PMOSs 33, 34 and 41 in the OP AMP 3B to be turned on and the NMOSs 12, 42 and 43 therein to be turned off. Also, the start-up signal EN is inverted from the “L” level to the “H” level (=VDD) by the inverter 35, thereby causing the NMOS 36 to be turned on. As a result, the node BIAS is fixed at the VDD, the output node MID is fixed at the VDD, the node NGATE is fixed at the VSS, and the output voltage OUT is fixed at the VDD. At the same time, because the NMOSs 42 and 43 are turned off, the current path from the VDD node to the VSS node is cut. Also, similarly to the first embodiment, since the output voltage OUT of the OP AMP 3B is fixed at the VDD, the PMOS 6 in FIG. 2 is turned off and all current paths in the constant-current generation circuit of FIG. 2 are thus cut. At the same time, the output terminal 8 is fixed at the VSS by the NMOS 5.

Thereafter, at the time when the start-up signal EN indicates the “H” level (=VDD) (a time 10 μs in FIG. 8 and FIG. 9), in the OP AMP 3B, the PMOSs 33, 34 and 41 are turned off and the NMOSs 12, 42 and 43 are turned on. Also, the start-up signal EN is inverted from the “H” level to the “L” level by the inverter 35, thereby causing the NMOS 36 to be turned off. As a result, the voltage of the node BIAS falls from the VDD to the vicinity of the voltage level VDD−Vtp, so that the PMOSs 21 and 31 are turned on. As the PMOSs 21 and 31 are turned on and the NMOSs 42 and 43 are turned on, the differential stage 20B and the amplification stage 30 are made active. Then, in order to make the feedback voltage INP equal to the input voltage INN, the voltage of the node NGATE rises from the VSS to the predetermined voltage level. At this time, in the present second embodiment, the NMOS 43 is turned on synchronously with the switching (“L” level→“H” level) timing of the start-up signal EN to form a short circuit between the output node MID fixed at the VDD in the reset period and the node NGATE. As a result, the voltage of the node NGATE rises from the VSS to a specific voltage level in advance.

The specific voltage level to which the voltage of the node NGATE rises is determined by the value of the VDD, the value of a parasitic capacitance of the output node MID and the value of a parasitic capacitance of the node NGATE. Assuming that the value of the parasitic capacitance of the output node MID is C3 and the value of the parasitic capacitance of the node NGATE is C4, the logical value of the specific voltage level can be expressed as in the following equation 2.
{C3/(C3+C4)}·VDD (2)

Thereafter, the voltage of the node NGATE rises to the predetermined voltage level and the output voltage OUT falls from the VDD to the predetermined voltage level, thereby making the feedback voltage INP equal to the input voltage INN. Thus, constant current can be obtained at the output terminal 8 similarly to the first embodiment.

(Effect of Second Embodiment)

According to the present second embodiment, the following effects (a) and (b) can be obtained.

(a) The PMOS 41 and NMOSs 42 and 43 are provided in the differential stage 20B of the OP AMP 3B. Thus, in the start-up operation of the constant-current generation circuit, a short circuit is formed between the output node MID of the differential stage 20B fixed at the VDD in the reset period and the node NGATE at the output side of the differential stage 20B fixed at the VSS in the reset period. As a result, the voltage of the node NGATE can more rapidly rise from the VSS to the predetermined voltage level by rising to the specific voltage level in advance synchronously with the switching timing of the start-up signal EN. Therefore, in the constant-current generation circuit, it is possible to reduce a time required until constant current is obtained at the output terminal 8 after start-up under the condition of setting the gain of the differential stage 20B of the OP AMP 3B to the small value.

(b) Although the MOS capacitance 27 for phase compensation is connected to the output node MID, a large capacitance value is generally used to secure the phase compensation. This means that the value of C3 in the equation 2 must be large, resulting in an increase in the specific voltage level to which the voltage of the node NGATE rises in the start-up operation. On the other hand, in the first embodiment, there is a need to make the value of C1 in the equation 1 large in order to increase the specific voltage level. This menas that the capacitance 37 of the large value must be additionally provided. The addition of only three MOS transistors, the PMOS 41 and NMOSs 42 and 43, in the second embodiment instead of the capacitance 37 in the first embodiment makes it possible to implement the circuit in a smaller layout space.

### THIRD EMBODIMENT

(Configuration of Third Embodiment)

The present invention is not limited to the above-described first and second embodiments, but various modifications thereof are possible. The following modified embodiments (A) and (B) may be adopted as a third embodiment of the present invention.

(A) In FIG. 1, FIG. 2 and FIG. 7, PMOSs may replace NMOSs and vice versa by changing the voltage polarity, or other transistors such as bipolar transistors may replace those MOS transistors. Further, other devices may be added or the existing devices may be eliminated.

(B) Although the OP AMPs 3 and 3B of FIG. 1 and FIG. 7 have been described for illustrative purposes to be used in the constant-current generation circuit of FIG. 2, they may be applied to other semiconductor devices equipped with OP AMPs 3 and 3B which need to be started up at high speed.

The present invention is not limited to the embodiments described above. Specifically, in the first embodiment, there is provided a capacitance between the control terminal 3c that receives the start-up signal EN and the node NGATE. The voltage of the node NGATE increases from the VSS to a specific voltage level (or, from the VSS by a predetermined or certain voltage) in response to a switching (“L” level→“H” level) of the start-up signal EN from the first level (=VSS) to the second level (=VDD). Additionally, in the second embodiment, there is provided a first switching circuit and a second switching circuit, instead of the capacitance 37 in the OP AMP 3 of the first embodiment, to increase the voltage of the node NGATE from the VSS to a specific voltage level by a certain voltage in response to a switching of the start-up signal EN from the first level (=VSS) to the second level (=VDD).

The present invention is not limited to the particular configuration or the circuit described above. In another aspect of the present invention, there is provided a voltage increasing circuit which increases the voltage of the node NGATE from the VSS to a specific voltage level (or, from the VSS by a predetermined or certain voltage) in response to a switching of the start-up signal EN from the first level (=VSS) to the second level (=VDD).

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

This application is based on Japanese Patent Application No. 2005-216828 which is hereby incorporated by reference.

What is claimed is:

1. An operational amplifier comprising:
a first input terminal for receiving a first input signal;
a second input terminal for receiving a second input signal;
a control terminal for receiving a start-up signal which makes transitions to a first logic level and a second logic level;
an output terminal;
reset means for resetting a first node to a second voltage, a second node to a first voltage which is different from the second voltage and the output terminal to the second voltage, respectively, when the start-up signal input to the control terminal indicates the first logic level, and disconnecting the first node from the second voltage, the second node from the first voltage and the output terminal from the second voltage, respectively, when the start-up signal is changed from the first logic level to the second logic level;
a differential stage made active when the start-up signal is changed to the second logic level and a voltage of the first node makes a transition to a predetermined level, for amplifying a difference between the first input signal input to the first input terminal and the second input signal input to the second input terminal and outputting the amplified difference to the second node;
an amplification stage made active when the voltage of the first node makes the transition to the predetermined level, for amplifying a voltage of the second node and outputting the amplified voltage to the output terminal; and
a capacitance connected between the control terminal and the second node.

2. An operational amplifier comprising:
a first input terminal for receiving a first input signal;
a second input terminal for receiving a second input signal;
a control terminal for receiving a start-up signal which makes transitions to a first logic level and a second logic level;
an output terminal;
reset means for resetting a first node to a second voltage, a second node to a first voltage which is different from the second voltage and the output terminal to the second voltage, respectively, when the start-up signal input to the control terminal indicates the first logic level, and disconnecting the first node from the second voltage, the second node from the first voltage and the output terminal from the second voltage, respectively, when the start-up signal is changed from the first logic level to the second logic level;
a differential stage made active when the start-up signal is changed to the second logic level and a voltage of the first node makes a transition to a predetermined level, for amplifying a difference between the first input signal input to the first input terminal and the second input signal input to the second input terminal and outputting the amplified difference from an output node thereof to the second node;
an amplification stage made active when the voltage of the first node makes the transition to the predetermined level, for amplifying a voltage of the second node and outputting the amplified voltage to the output terminal;
first switching means for holding the output node at the second voltage when the start-up signal indicates the first logic level, and disconnecting the output node from the second voltage to make the differential stage active when the start-up signal is changed to the second logic level; and
second switching means for isolating the output node and the second node from each other when the start-up signal indicates the first logic level and connecting the output node and the second node with each other when the start-up signal is changed from the first logic level to the second logic level.

3. A constant-current generation circuit comprising:
the operational amplifier according to claim 1; and
a transistor for outputting constant current in response to an output signal from the output terminal of the operational amplifier,
wherein a reference voltage is input to the first input terminal of the operational amplifier and a voltage based on the output current from the transistor is feedback-input to the second input terminal of the operational amplifier.

4. A constant-current generation circuit comprising:
the operational amplifier according to claim 2; and
a transistor for outputting constant current in response to an output signal from the output terminal of the operational amplifier,
wherein a reference voltage is input to the first input terminal of the operational amplifier and a voltage based on the output current from the transistor is feedback-input to the second input terminal of the operational amplifier.

5. The constant-current generation circuit as set forth in claim 3, further comprising third switching means for fixing the second input terminal of the operational amplifier at the first voltage when the start-up signal indicates the first logic level and disconnecting the second input terminal from the first voltage when the start-up signal is changed from the first logic level to the second logic level.

6. The constant-current generation circuit as set forth in claim 4, further comprising third switching means for fixing the second input terminal of the operational amplifier at the first voltage when the start-up signal indicates the first logic level and disconnecting the second input terminal from the first voltage when the start-up signal is changed from the first logic level to the second logic level.

7. An operational amplifier comprising:
a first input terminal for receiving a first input signal;
a second input terminal for receiving a second input signal;
a control terminal for receiving a start-up signal which makes transitions to a first logic level and a second logic level;
an output terminal;
reset means for resetting a first node to a second voltage, a second node to a first voltage which is different from the second voltage and the output terminal to the second voltage, respectively, when the start-up signal input to the control terminal indicates the first logic level, and disconnecting the first node from the second voltage, the second node from the first voltage and the output terminal from the second voltage, respectively, when the start-up signal is changed from the first logic level to the second logic level;
a differential stage made active when the start-up signal is changed to the second logic level and a voltage of the first node makes a transition to a predetermined level, for amplifying a difference between the first input signal input to the first input terminal and the second input signal input to the second input terminal and outputting the amplified difference to the second node;
an amplification stage made active when the voltage of the first node makes the transition to the predetermined level, for amplifying a voltage of the second node and outputting the amplified voltage to the output terminal; and
a voltage increasing circuit which increases the voltage of the second node to a specific voltage level in response to a switching of the start-up signal from the first logic level to the second logic level.

8. A constant-current generation circuit comprising:
the operational amplifier according to claim 7; and
a transistor for outputting constant current in response to an output signal from the output terminal of the operational amplifier,
wherein a reference voltage is input to the first input terminal of the operational amplifier and a voltage based on the output current from the transistor is feedback-input to the second input terminal of the operational amplifier.

9. The constant-current generation circuit as set forth in claim 8, further comprising third switching means for fixing the second input terminal of the operational amplifier at the first voltage when the start-up signal indicates the first logic level and disconnecting the second input terminal from the first voltage when the start-up signal is changed from the first logic level to the second logic level.
